(19) United States
(12) Patent Application Publication
(10) Pub. No.: US 2026/0020502 A1
(43) Pub. Date: Jan. 15, 2026

(54) QUANTUM DEVICE ASSEMBLY, QUANTUM DEVICE MANUFACTURING METHOD, AND QUANTUM DEVICE ASSEMBLY MANUFACTURING METHOD

(71) Applicant: NEC Corporation, Tokyo (JP)

(72) Inventor: Shun YANAI, Tokyo (JP)

(73) Assignee: NEC Corporation, Tokyo (JP)

(21) Appl. No.: 19/248,665

(22) Filed: Jun. 25, 2025

(30) Foreign Application Priority Data
Jul. 12, 2024 (JP) 2024-112803

(51) Int. Cl. H10N 60/12; H10N 60/01; H10N 60/80

(52) U.S. Cl. CPC H10N 60/12; H10N 60/0912; H10N 60/805

(57) ABSTRACT

A quantum device assembly includes mask layers including a first sacrificial layer and a second sacrificial layer on a superconductor layer. Focusing on the mask layers, a content rate of an organic material in the first sacrificial layer is smaller than a content rate of the organic material in the second sacrificial layer.

This application is based upon and claims the benefit of priority from Japanese Patent Application No. 2024-112803, filed on Jul. 12, 2024, the disclosure of which is incorporated herein in its entirety by reference.

### TECHNICAL FIELD

The present disclosure relates to a quantum device assembly, a quantum device manufacturing method, and a quantum device assembly manufacturing method.

### BACKGROUND ART

A quantum device including a qubit circuit is known. In such a quantum device, it is known to use Josephson coupling for the qubit circuit.

For example, WO 2023/243080 A1 describes “a method for manufacturing a Josephson junction device, including: forming, on a substrate, a mask layer in which a plurality of mask patterns, each of which has a first opening that extends in a first direction and a second opening that extends in a second direction that intersects the first direction and that intersects the first opening, is arranged in the first direction; forming, using the mask layer as a mask, a first film above the substrate by first film formation from obliquely above in the first direction, and forming, after the forming the first film, a second film above the substrate by second film formation from obliquely above in a direction different from the direction of the first film formation relative to the substrate, and forming a first superconducting film that includes the first film and the second film; forming an insulating film on a surface of the first superconducting film; and forming, using the mask layer as a mask, a third film that has a region in which the third film overlaps the first superconducting film via the insulating film above the substrate by third film formation from obliquely above in the second direction, and forming a second superconducting film that includes the third film”.

The mask layer is formed by two layers of resist.

### SUMMARY

An example of a quantum device assembly of the present disclosure includes a substrate, a superconductor layer laminated on the substrate, a first sacrificial layer laminated on the superconductor layer, and a second sacrificial layer laminated on the first sacrificial layer, and a content rate of an organic material in the first sacrificial layer is smaller than a content rate of the organic material in the second sacrificial layer.

An example of a quantum device manufacturing method of the present disclosure uses a quantum device assembly including a substrate, a superconductor layer laminated on the substrate, a first sacrificial layer laminated on the superconductor layer, and a second sacrificial layer laminated on the first sacrificial layer, in which a content rate of an organic material in the first sacrificial layer is smaller than a content rate of the organic material in the second sacrificial layer, and the quantum device manufacturing method includes providing an opening in the second sacrificial layer by a beam, removing the first sacrificial layer via the opening, laminating a first deposition pattern on the superconductor layer and the substrate, oxidizing a surface of the first deposition pattern, and laminating a second deposition pattern at a laterally shifted position relative to the first deposition pattern in such way that a part of the second deposition pattern overlaps the first deposition pattern.

An example of a quantum device assembly manufacturing method of the present disclosure includes laminating a superconductor layer on a substrate, laminating a first sacrificial layer on the superconductor layer, and laminating a second sacrificial layer on the first sacrificial layer, and a content rate of an organic material in the first sacrificial layer is smaller than a content rate of the organic material in the second sacrificial layer.

### BRIEF DESCRIPTION OF THE DRAWINGS

FIG. 1 is a cross-sectional view I illustrating an example of a configuration of a quantum device assembly according to the present disclosure;

FIG. 2 is a cross-sectional view II illustrating an example of the configuration of the quantum device assembly according to the present disclosure;

FIG. 3 is a plan view illustrating an example of the configuration of the quantum device assembly according to the present disclosure;

FIG. 4 is a cross-sectional view III illustrating an example of the configuration of the quantum device assembly according to the present disclosure;

FIG. 5 is a flowchart I illustrating an example of processing of a quantum device assembly manufacturing method according to the present disclosure;

FIG. 6 is a flowchart I illustrating an example of processing of a quantum device manufacturing method according to the present disclosure;

FIG. 7A is first in a supplemental view I illustrating an example of the processing of the quantum device manufacturing method according to the present disclosure;

FIG. 7B is second in a supplemental view I illustrating an example of the processing of the quantum device manufacturing method according to the present disclosure;

FIG. 7C is third in a supplemental view I illustrating an example of the processing of the quantum device manufacturing method according to the present disclosure;

FIG. 8A is first in a supplemental view illustrating an example of the processing of the quantum device manufacturing method according to a modification;

FIG. 8B is second in a supplemental view illustrating an example of the processing of the quantum device manufacturing method according to a modification;

FIG. 8C is third in a supplemental view illustrating an example of the processing of the quantum device manufacturing method according to a modification;

FIG. 9 is a perspective view illustrating an example of the configuration of the quantum device assembly according to the present disclosure;

FIG. 10A is first in a supplemental view II illustrating an example of the processing of the quantum device manufacturing method according to the present disclosure;

FIG. 10B is second in a supplemental view II illustrating an example of the processing of the quantum device manufacturing method according to the present disclosure;

FIG. 10C is third in a supplemental view II illustrating an example of the processing of the quantum device manufacturing method according to the present disclosure;

FIG. 11 is a cross-sectional view IV illustrating an example of the configuration of the quantum device assembly according to the present disclosure;

FIG. 12 is a flowchart II illustrating an example of the processing of the quantum device assembly manufacturing method according to the present disclosure; and

FIG. 13 is a flowchart II illustrating an example of the processing of the quantum device manufacturing method according to the present disclosure.

### EXAMPLE EMBODIMENT

Hereinafter, example embodiments according to the present disclosure will be described with reference to the drawings. The drawings and specific configurations used in the example embodiments are not to be used for interpretation of the disclosure. In all the drawings, the same or related configurations are denoted by the same reference signs, and the common description will be omitted.

In the present disclosure, the drawings are associated with one or more example embodiments.

### First Example Embodiment

Hereinafter, an example embodiment according to the present disclosure will be described with reference to the drawings.

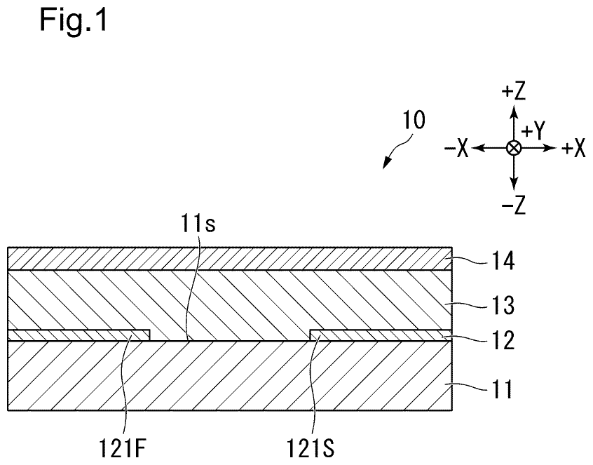

First, an example of a quantum device assembly in the present disclosure will be described with reference to FIGS. 1 to 4.

Hereinafter, a direction in which patterns are laminated is referred to as a Z direction. One direction in a substrate surface 11s to be described later is referred to as an X direction. A direction intersecting the X direction in the substrate surface 11s is referred to as a Y direction. One of the X direction is defined as a +X direction, and the other of the X direction is defined as a −X direction. One of the Y direction is defined as a +Y direction, and the other of the Y direction is defined as a −Y direction. One of the Z direction is defined as a +Z direction, and the other of the Z direction is defined as a −Z direction. A direction from the −X direction to the +X direction is also referred to as a deposition direction D1. In contrast, a direction from the +X direction to the −X direction is also referred to as a deposition direction D1′. The Y direction is also referred to as a deposition direction D2. The Z direction is also referred to as a lamination direction D3.

For example, the X direction, the Y direction, and the Z direction may be directions orthogonal to each other. For example, the substrate surface 11s may be a surface along an XY plane and facing the +Z direction. For example, the +Z direction may be an upward direction.

Unless otherwise specified below, a shape of a first deposition pattern and a position of the first deposition pattern are the shape and the position when viewed from the Z direction. The same applies to a shape of a second deposition pattern and a position of the second deposition pattern.

### (Configuration of Quantum Device Intermediate)

A quantum device assembly 10 is used as a workpiece when a quantum device 100 to be described later is manufactured.

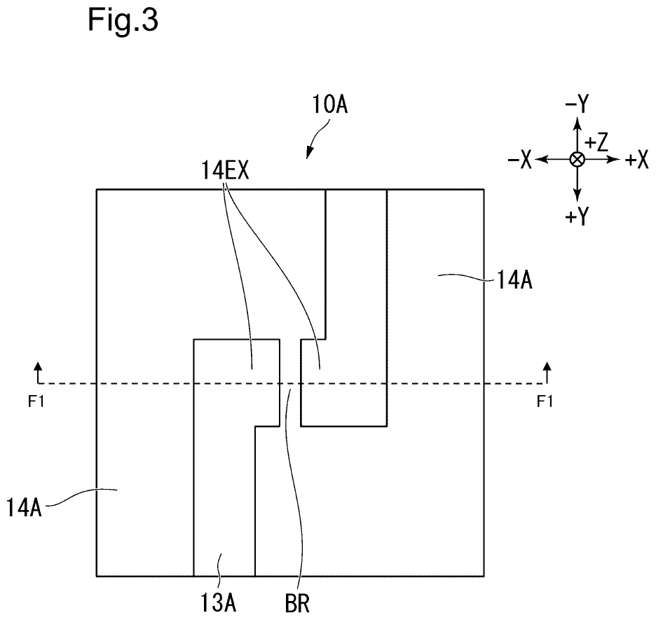

As illustrated in FIG. 1, the quantum device assembly 10 includes a substrate 11, a superconductor layer 12, a first sacrificial layer 13, and a second sacrificial layer 14. FIG. 1 is a cross-sectional view taken along a cutting line F1-F1 in FIG. 3.

### (Configuration of Substrate)

The substrate 11 has the substrate surface 11s.

The substrate surface 11s includes a unit where electrodes and the like included in the superconductor layer 12 are laminated and a unit where the substrate surface 11s is exposed before formation of the sacrificial layers because the electrodes and the like are not laminated. The electrodes and the like also include a wiring pattern to be described later.

For example, the substrate 11 may be formed by a material such as silicon, sapphire, or a compound semiconductor. In the quantum device assembly 10 of the present disclosure, silicon is adopted.

For example, the substrate 11 may be formed by single crystal, polycrystal, amorphous, or the like.

For example, the substrate 11 may be a high-resistance semiconductor substrate.

### (Configuration of Superconductor Layer)

The superconductor layer 12 is laminated on the substrate surface 11s of the substrate 11.

The superconductor layer 12 includes the electrodes and the like. For example, as the superconductor layer 12, two electrodes constituting a qubit are patterned on the substrate surface 11s before deposition of a Josephson junction (hereinafter, also referred to as “JJ”) 5. A resonator for reading, a ground plane, or the like may be patterned on the substrate surface 11s. For example, each pattern of the superconductor layer 12 may be patterned by reactive ion etching, wet etching, or the like.

The patterning of the superconductor layer 12 may be deposited by, for example, sputtering, vapor deposition, or chemical vapor deposition (CVD).

A superconductor (alternatively, superconducting) material is used for the electrodes. The superconductor (alternatively, superconducting) material is a material exhibiting superconducting characteristics at equal to or less than a superconducting critical temperature.

The superconductor layer 12 includes a first electrode unit 121F and a second electrode unit 121S separated from the first electrode unit 121F in a first direction.

### (Configuration of Each Electrode)

The two electrodes (the first electrode unit 121F and the second electrode unit 121S) included in the superconductor layer 12 include titanium nitride, titanium niobium nitride, tantalum, or molybdenum-rhenium alloy (MoRe). When a cavity 13c to be described later is provided in the first sacrificial layer 13 by vapor-phase hydrogen fluoride (Vapor BHF), surfaces of the electrodes including these materials are cleaned. With this configuration, argon milling performed on the surfaces of the electrodes before aluminum deposition is unnecessary.

The two electrodes (the first electrode unit 121F and the second electrode unit 121S) may include niobium or aluminum, and in that case, a material other than the vapor-phase hydrogen fluoride may be used for formation of the cavity.

### (Outline of Quantum Device Intermediate)

The quantum device assembly 10 of the present disclosure includes mask layers including the first sacrificial layer 13 and the second sacrificial layer 14. The first sacrificial layer 13 that is closer to the substrate surface 11s than the second sacrificial layer 14 and is in contact with the substrate surface 11s, the first electrode unit 121F, and the second electrode unit 121S has an inorganic material as a main component as described later.

As described later, the first sacrificial layer 13 is to be removed. Here, when a content rate of the inorganic material in the first sacrificial layer 13 is larger than a content rate of the inorganic material in the second sacrificial layer 14, the material remaining on the substrate surface 11s or a surface of the superconductor layer 12 without being completely removed can be reduced after the removal of the first sacrificial layer 13. Alternatively, a separate process for surface cleaning is unnecessary or simplified.

Therefore, the quantum device assembly 10 of the present disclosure is characterized by a smaller content rate of an organic material in the first sacrificial layer 13 than a content rate of the organic material in the second sacrificial layer 14.

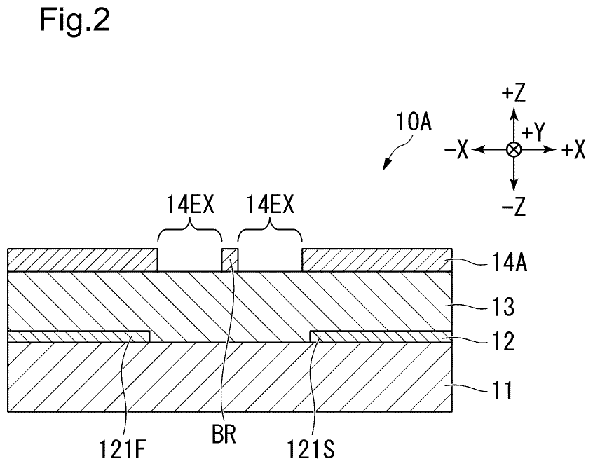

As illustrated in FIG. 2, the second sacrificial layer 14 may have at least one opening 14EX. For example, the second sacrificial layer 14 in the following disclosure is a second sacrificial layer 14A having a plurality of the openings 14EX. In FIG. 2, the first sacrificial layer 13 communicates with the openings 14EX. FIG. 3 is a plan view of a quantum device assembly 10A as viewed from the lamination direction D3. In the second sacrificial layer 14, a bridge BR exists between the plurality of openings 14EX. A dimension of the bridge BR in the deposition direction D1 (or the deposition direction D1′) is smaller than a dimension of the opening 14EX in the same direction. For example, the dimension of the bridge BR in the deposition direction D1 (or the deposition direction D1′) is about ¼ to ½ of the dimension of the opening 14EX in the same direction. By setting the dimension of the bridge BR in this manner, a first deposition layer 2 and a second deposition layer 4 are easily laminated by an oblique deposition method.

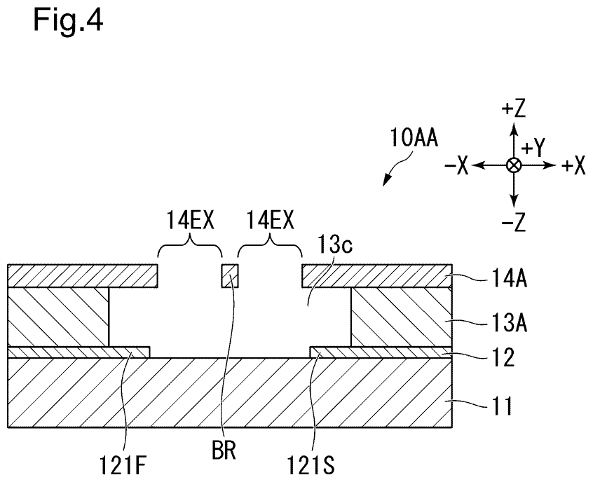

As illustrated in FIG. 4, the first sacrificial layer 13 may be a first sacrificial layer 13A having the cavity 13c.

### (Configuration of First Sacrificial Layer)

The first sacrificial layer 13 (first sacrificial layer 13A) is laminated on the superconductor layer 12.

The first sacrificial layer 13 (first sacrificial layer 13A) has silicon oxide or silicon nitride as the main component. A ratio of the silicon oxide and/or the silicon nitride included in the first sacrificial layer 13 is preferably equal to or more than 90%, more preferably equal to or more than 99%, and still more preferably equal to or more than 99.9% as a mass percentage.

Examples of a method for forming the first sacrificial layer 13 include a method using plasma CVD (plasma enhanced chemical vapor deposition (PECVD)) and a chemical vapor deposition (CVD).

In FIG. 4, the first sacrificial layer 13A has the cavity 13c. The cavity 13c is an opening that includes at least one shape of the openings 14EX when viewed from the lamination direction D3. In other words, a dimension of the cavity 13c in the X direction is larger than the dimension of the opening 14EX in the same direction. An opening shape of the cavity 13c is also referred to as an undercut shape, and processing for creating the undercut shape is also referred to as undercut processing. The cavity 13c communicates with the openings 14EX.

The cavity 13c is provided in the first sacrificial layer 13A by removing a part of the first sacrificial layer 13 by vapor-phase hydrogen fluoride passing through the openings 14EX.

The reactive ion etching may be adopted instead of reaction processing with the vapor-phase hydrogen fluoride. The reactive ion etching may be either isotropic etching or anisotropic etching. However, the isotropic etching is easier to create the undercut shape than the anisotropic etching.

### (Second Sacrificial Layer)

The second sacrificial layer 14 (second sacrificial layer 14A) is laminated on the first sacrificial layer 13.

The second sacrificial layer 14 (second sacrificial layer 14A) includes an organic polymer. Examples of the organic polymer include polymethyl methacrylate (PMMA) and polydimethylglutarimide (PMGI). The second sacrificial layer 14 (second sacrificial layer 14A) may include a monomer.

Examples of a method for forming the second sacrificial layer 14 include a method for spin-coating a resist for electron beam (EB) exposure. In this case, the above materials are preferable as a resist material.

In a step of providing the cavity 13c in the first sacrificial layer 13, the second sacrificial layer 14 needs to be kept in shape without being etched as much as possible. In this respect, the organic material such as the organic polymer is preferable in that resistance to hydrogen fluoride and ion etching used in the step of providing the cavity 13c is high.

As illustrated in FIG. 2 again, the second sacrificial layer 14A has the plurality of openings 14EX. The openings 14EX are provided in the second sacrificial layer 14A by development with a developer after being drawn on the second sacrificial layer 14 by an EB exposure device.

### (Difference in Opening Shape by Deposition Scheme of Josephson Junction)

For example, using the two mask layers (the layers including the first sacrificial layer 13 and the second sacrificial layer 14), a manufacturer performs deposition of a Josephson junction by a method such as a Doran bridge method or a Manhattan method.

Therefore, an opening shape of the second sacrificial layer 14 varies depending on a method that can be taken by the manufacturer.

### (Difference in Opening Shape by Doran Bridge Method)

When viewed from the lamination direction D3, the second sacrificial layer 14 has the plurality of openings 14EX between the first electrode unit 121F and the second electrode unit 121S.

### (Difference in Opening Shape by Manhattan Method)

When viewed from the lamination direction D3, the second sacrificial layer 14 has at least one opening 14EX′. The opening 14EX′ includes a first slit 14SL1 along the deposition direction D1 and a second slit 14SL2 along the deposition direction D2. The first slit 14SL1 and the second slit 14SL2 are coupled. When viewed from the lamination direction D3, the opening 14EX′ has a + shape, an L shape, and a T shape.

The opening 14EX′ will be described later.

### (Method for Method for Manufacturing Intermediate)

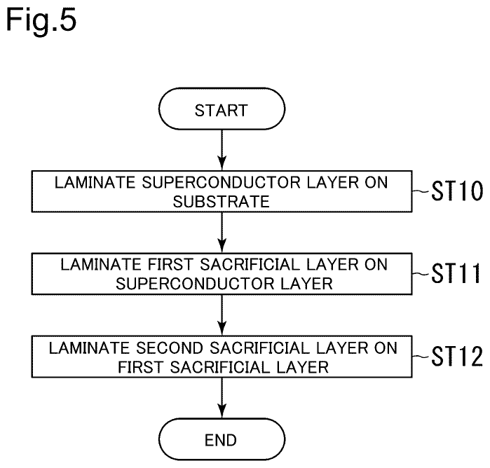

An example of a quantum device assembly manufacturing method will be described with reference to FIG. 5. The quantum device assembly manufacturing method in the present example embodiment is implemented according to a flow illustrated in FIG. 5.

The following description relates to a part of the quantum device assembly manufacturing method of the present disclosure.

First, the manufacturer laminates the superconductor layer 12 on the substrate 11 (step ST10: step of laminating).

Following the implementation of step ST10, the manufacturer laminates the first sacrificial layer 13 on the superconductor layer 12 (step ST11: step of laminating the first sacrificial layer). The first sacrificial layer 13 may include or does not have to include the organic material. At this time, the content rate of the organic material in the first sacrificial layer 13 is smaller than the content rate of the organic material in the second sacrificial layer 14.

Following the implementation of step ST11, the manufacturer laminates the second sacrificial layer 14 on the first sacrificial layer 13 (step ST12: step of laminating the second sacrificial layer on the first sacrificial layer).

Following the implementation of step ST12, the manufacturer may provide the at least one or more openings 14EX (openings 14EX′) in the second sacrificial layer 14. When the opening 14EX is provided, the manufacturer provides the plurality of openings 14EX in the second sacrificial layer 14. When the opening 14EX′ is provided, the manufacturer provides the at least one opening 14EX′ in the second sacrificial layer 14. At this time, the manufacturer may provide the cavity 13c in the first sacrificial layer 13.

### (Configuration of Quantum Device)

Before describing an example of a quantum device manufacturing method, the quantum device 100 manufactured by processing the quantum device assembly 10 will be described.

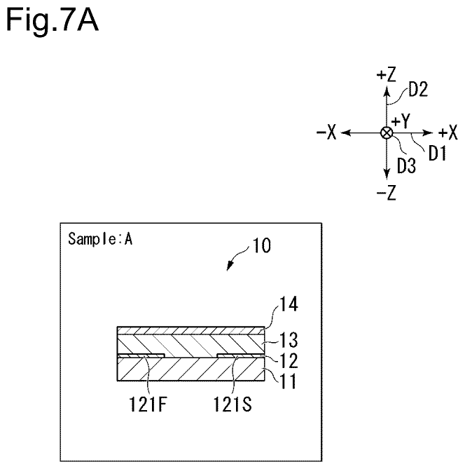

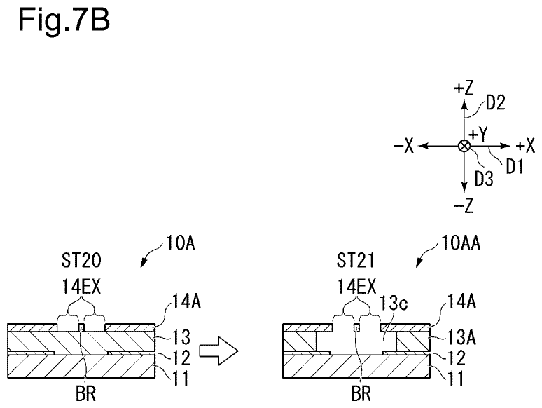

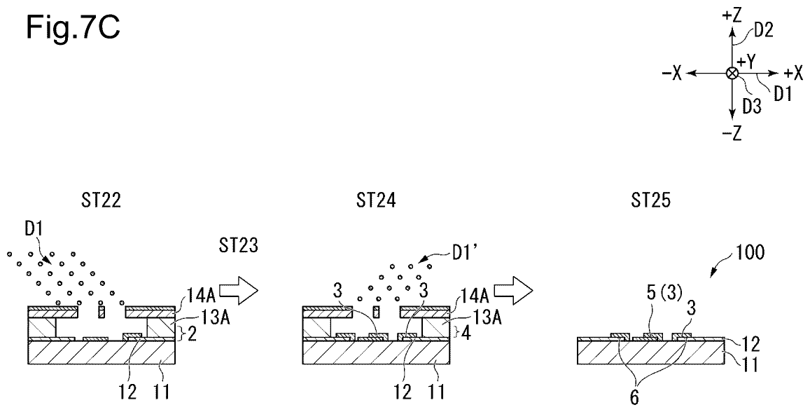

As illustrated in FIG. 7C, the quantum device 100 includes the substrate 11, the superconductor layer 12, the first deposition layer 2, an oxide film 3, the second deposition layer 4, and the at least one Josephson junction (JJ) 5. The quantum device 100 may further include a parasitic junction 6.

### (Configuration of First Deposition Layer)

The first deposition layer 2 is a pattern (hereinafter, also referred to as a “first deposition pattern”) for depositing the JJ 5 together with the second deposition layer 4.

The first deposition layer 2 is partially laminated on the superconductor layer 12.

For example, the first deposition layer 2 may be a deposition layer deposited on the superconductor layer 12 from an oblique direction relative to the Z direction by the oblique deposition method.

For example, the first deposition layer 2 may be formed by aluminum as a superconductor.

The oxide film is formed by oxidizing a surface of the first deposition layer 2. For example, AlOx having a predetermined film thickness may be formed on the surface of the first deposition layer 2 by thermally oxidizing the surface of the first deposition layer 2 as the aluminum.

### (Configuration of Second Deposition Layer)

The second deposition layer 4 is partially laminated on the first deposition layer 2. The second deposition layer 4 may be partially laminated on the superconductor layer 12.

For example, the second deposition layer 4 may be a deposition layer deposited on the superconductor layer 12 from an oblique direction different from that in the case of the first deposition layer 2 relative to the Z direction by the oblique deposition method.

For example, the second deposition layer 4 may be formed by aluminum as a superconductor.

The JJ 5 is a structure including a structure of a “superconductor-insulator thin film-superconductor”. In the quantum device of the present disclosure, the JJ 5 is achieved by “aluminum-AlOx-aluminum”.

In the quantum device 100 of the present disclosure, a plurality of the JJs 5 may be deposited.

### (Quantum Device Manufacturing Method)

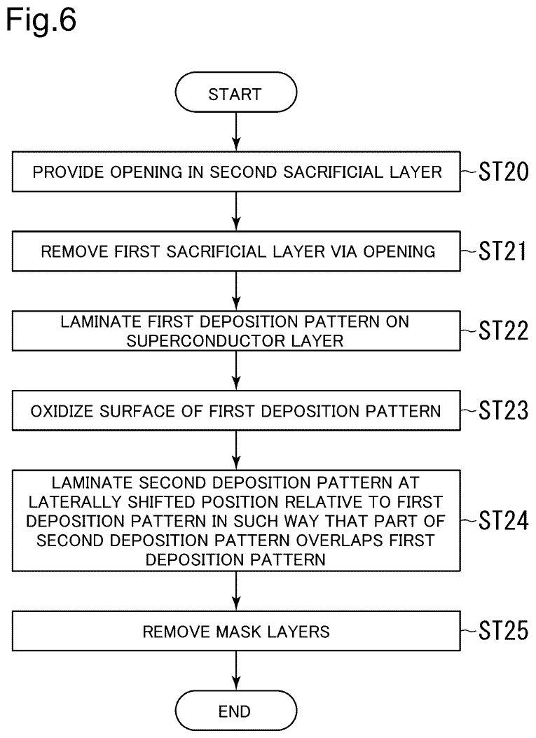

An example of the quantum device manufacturing method will be described with reference to FIGS. 6, 7A, 7B and 7C.

The quantum device manufacturing method in the present example embodiment is implemented according to a flow illustrated in FIG. 6. FIG. 7A, 7B and 7C are a supplemental view of each step in FIG. 6.

The following description relates to a part of the quantum device manufacturing method of the present disclosure.

In the quantum device manufacturing method of the present disclosure, as illustrated in FIG. 7A, the quantum device assembly 10 defined as Sample: A is used. The target quantum device assembly 10 has the following characteristics.

The quantum device assembly 10 includes the substrate, the superconductor layer laminated on the substrate, the first sacrificial layer laminated on the superconductor layer, and the second sacrificial layer laminated on the first sacrificial layer, and the second sacrificial layer includes the organic material, and the content rate of the organic material in the first sacrificial layer is smaller than the content rate of the organic material in the second sacrificial layer.

First, as illustrated in FIG. 7B, using the quantum device assembly 10, the manufacturer provides the at least one opening 14EX in the second sacrificial layer 14 by an electron beam (EB) (step ST20: providing the opening). For example, in step ST20, the plurality of openings 14EX may be provided in the second sacrificial layer 14. The openings 14EX are provided in the second sacrificial layer 14A by development with the developer after being drawn on the second sacrificial layer 14 by the EB exposure device.

As in the quantum device assembly 10A illustrated in FIG. 2, when the quantum device assembly already has the opening 14EX, the manufacturer may omit step ST20.

Next, as illustrated in FIG. 7C, the manufacturer removes the first sacrificial layer 13 via the opening 14EX (step ST21: step of removing the first sacrificial layer). When step ST20 is omitted, the manufacturer starts the processing from step ST21.

When the quantum device assembly already has the cavity 13c as in a quantum device assembly 10AA illustrated in FIG. 4, the manufacturer may omit step ST21.

For example, the manufacturer removes a part of the first sacrificial layer 13 with vapor-phase hydrogen fluoride.

Next, the manufacturer laminates the pattern of the first deposition layer 2 on the superconductor layer 12 and the substrate 11 (step ST22: step of laminating the first deposition pattern). When step ST21 is omitted, the manufacturer starts the processing from step ST22.

For example, in step ST22, the manufacturer laminates the pattern of the first deposition layer 2 on the superconductor layer 12 and the substrate 11 from a direction inclined in the first direction (deposition direction D1) relative to the lamination direction D3.

Next, the manufacturer oxidizes the surface of the first deposition layer 2 (step ST23: step of oxidizing the surface of the first deposition pattern). The oxide film 3 as an insulating film is thus deposited on the surface of the first deposition layer 2.

Next, the manufacturer laminates the second deposition layer 4 at a position shifted in the X direction relative to the first deposition layer 2 in such a way that a part of the second deposition layer 4 overlaps the first deposition layer 2 (step ST24: step of laminating the second deposition pattern).

For example, in step ST24, the manufacturer laminates, via the oxide film 3, a part of the second deposition layer 4 on the first deposition layer 2 from a direction inclined in a second direction (deposition direction D1′) relative to the lamination direction D3.

The JJ 5 is thus deposited on the substrate surface 11s.

At this time, the parasitic junction 6 may be deposited on the surface of the superconductor layer 12. The parasitic junction 6 is a structure including a structure of “superconductor-superconductor-insulator thin film”. The parasitic junction 6 is less likely to cause loss reduction of qubits.

Next, the manufacturer removes the mask layers including the first sacrificial layer 13 and the second sacrificial layer 14 (step ST25).

The second sacrificial layer 14 and a deposition layer of AL deposited on the second sacrificial layer 14 are lifted off with a peeling solution. Next, the first sacrificial layer 13 is removed by the vapor-phase hydrogen fluoride.

### (End)

### (Operation and Effect)

According to the quantum device assembly of the present disclosure, the quantum device assembly 10 includes the mask layers including, on the superconductor layer 12, the first sacrificial layer 13 and the second sacrificial layer 14.

Focusing on the mask layers, the content rate of the organic material in the first sacrificial layer 13 is smaller than the content rate of the organic material in the second sacrificial layer 14.

Therefore, when the quantum device 100 is manufactured from the quantum device assembly 10, since the first sacrificial layer 13 is removed after the second sacrificial layer 14 is removed, the organic material is less likely to adhere to the superconductor layer 12.

Therefore, the quantum device assembly according to the present disclosure can reduce adhesion of an organic substance to a qubit circuit.

A method of removing the organic substance adhering to the qubit circuit by a surface cleaning process such as the argon milling is also conceivable, but this leads to an increase in the number of processes. In a case where the organic substance adheres to the qubit circuit, a probability that undesirable de-coherence of a qubit occurs may increase depending on an amount of the adhered organic substance. Therefore, the quantum device assembly of the present disclosure capable of reducing a residue of the organic material as described above can reduce the probability of occurrence of the de-coherence in the quantum device manufactured using the quantum device assembly.

According to the quantum device manufacturing method of the present disclosure, the quantum device assembly includes the mask layers including the first sacrificial layer and the second sacrificial layer on the superconductor layer.

Focusing on the mask layers, the content rate of the organic material in the first sacrificial layer is smaller than the content rate of the organic material in the second sacrificial layer.

Therefore, when the quantum device is manufactured from the quantum device assembly, since the first sacrificial layer is removed after the second sacrificial layer is removed, the organic material is less likely to adhere to the superconductor layer.

Therefore, the quantum device manufacturing method according to the present disclosure can reduce adhesion of the organic substance to the qubit circuit.

According to the quantum device assembly manufacturing method of the present disclosure, the quantum device assembly includes the mask layers including the first sacrificial layer and the second sacrificial layer on the superconductor layer.

Focusing on the mask layers, the content rate of the organic material in the first sacrificial layer is smaller than the content rate of the organic material in the second sacrificial layer.

Therefore, when the quantum device is manufactured from the quantum device assembly, since the first sacrificial layer is removed after the second sacrificial layer is removed, the organic material is less likely to adhere to the superconductor layer.

Therefore, the quantum device assembly manufacturing method according to the present disclosure can reduce adhesion of the organic substance to the qubit circuit.

The quantum device manufacturing method in a comparative example will be described.

The Josephson junction 5 is deposited by the method such as the Doran bridge method or the Manhattan method using two layers of a resist for creation of qubits. Dielectric loss is known as one factor of the loss reduction of the qubits. Adhesion of the resist to the surface of the wiring layer (superconductor layer 12) included in the quantum device causes the dielectric loss. It is considered that methyl methacrylate (MMA), PMMA, PMGI, and the like mentioned in the second sacrificial layer 14 can cause the dielectric loss.

Therefore, the loss reduction of the qubits due to the dielectric loss has been a problem.

In contrast to the comparative example, according to the quantum device assembly, the quantum device manufacturing method, and the quantum device assembly manufacturing method of the present disclosure, the resist on the lower layer positioned on a side of the substrate surface 11s of the two layers of resist is replaced with SiO2 deposited by sputtering or the like. With this configuration, it is possible to suppress adhesion of the organic substance derived from the resist to the surface of the wiring layer (superconductor layer 12) when the Josephson junction 5 is deposited. As a result, an energy relaxation time of the qubits is expected to be improved.

The quantum device assembly 10 of the present disclosure can obtain the following effects by “including the substrate 11, the superconductor layer 12 laminated on the substrate 11, the first sacrificial layer 13 laminated on the superconductor layer 12, and the second sacrificial layer 14 laminated on the first sacrificial layer 13, and the content rate of the organic material in the first sacrificial layer 13 is smaller than the content rate of the organic material in the second sacrificial layer 14”.

According to the quantum device assembly 10 of the present disclosure includes the mask layers including the first sacrificial layer 13 and the second sacrificial layer 14 on the superconductor layer 12.

Focusing on the mask layers, the content rate of the organic material in the first sacrificial layer 13 is smaller than the content rate of the organic material in the second sacrificial layer 14.

Therefore, when the quantum device 100 is manufactured from the quantum device assembly 10, since the first sacrificial layer 13 is removed after the second sacrificial layer 14 is removed, the organic material is less likely to adhere to the superconductor layer 12.

Therefore, the quantum device assembly 10 according to the present disclosure can reduce adhesion of the organic substance to the qubit circuit.

The quantum device assembly 10A of the present disclosure can further obtain the effect that “the cavity 13c is easily formed by the reactive ion etching via the openings 14EX” by “the superconductor layer 12 including the first electrode unit 121F and the second electrode unit 121S separated from the first electrode unit 121F in the first direction, in which the second sacrificial layer 14A includes the openings 14EX between the first electrode unit 121F and the second electrode unit 121S when viewed from the lamination direction D3”.

In the first example embodiment, the deposition of the JJ 5 by the Doran bridge method has been described. For example, equal to or more than two openings 14EX are needed in the deposition of the JJ 5 by the Doran bridge method. On the other hand, in the deposition of the JJ 5 by the Manhattan method indicated in a second example embodiment, the at least one opening 14EX′ is needed.

In the quantum device assembly 10A of the present disclosure, the second sacrificial layer 14 may have equal to or more than three openings 14EX between the first electrode unit 121F and the second electrode unit 121S. At this time, a plurality of the JJs 5 may be deposited. In this case, the plurality of Josephson junctions connected in series is obtained. Similar advantages are conceivable also in a case where there is the plurality of openings 14EX′.

In the quantum device assembly 10AA of the present disclosure, the following effects can be further obtained by “the first sacrificial layer 13 having the cavity 13c communicating with the openings 14EX.

The Josephson junction 5 can be deposited via the at least one opening 14EX and the cavity 13c in the second sacrificial layer 14.

As described above, the effect that “the JJ 5 can be stably deposited by the oblique deposition method via the at least one opening 14EX and the cavity 13c” can also be obtained.

In the present disclosure, when “the cavity 13c is an opening that includes the shape of the at least one opening 14EX when viewed from the lamination direction D3”, the opening shape of the cavity 13c is the undercut shape. At this time, the first deposition layer 2 (second deposition layer 4) is less likely to adhere to the first sacrificial layer 13. Therefore, the first deposition layer 2 (second deposition layer 4) is easily removed.

In the quantum device assembly 10, 10A, or 10AA of the present disclosure, by “the first sacrificial layer 13 including silicon oxide or silicon nitride”, the manufacturer can further selectively remove the first sacrificial layer 13 without damaging the first deposition layer 2 and the second deposition layer 4 by using the vapor-phase hydrogen fluoride.

In the quantum device assembly 10, 10A, or 10AA of the present disclosure, further by “the second sacrificial layer including a polymer”, drawing on the second sacrificial layer 14 by the EB exposure device is easily performed. A junction pattern of the JJ 5 is controlled via the at least one opening 14EX provided in the second sacrificial layer 14A by development with the developer after drawing.

As described above, it is possible to obtain the effect that “the junction pattern of the JJ 5 is easily controlled”.

In the quantum device assembly 10, 10A, or 10AA of the present disclosure, further by “the superconductor layer including titanium nitride, titanium niobium nitride, tantalum, or MoRe”, the surfaces of the electrodes are cleaned when the cavity 13c is provided in the first sacrificial layer 13A by the vapor-phase hydrogen fluoride (Vapor BHF). With this configuration, the argon milling performed on the surfaces of the electrodes before the aluminum deposition is unnecessary.

### (Modification)

Components common to those in the above disclosure are denoted by the same reference signs, and detailed description of the components will be omitted.

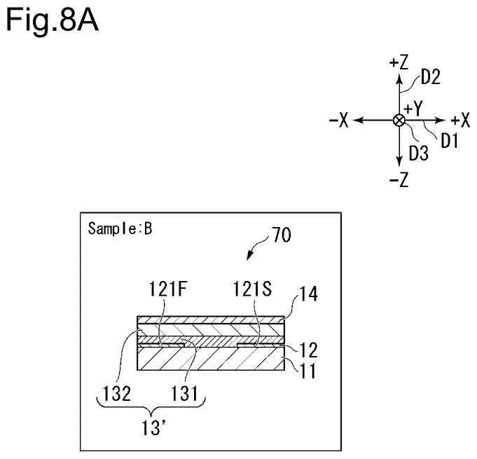

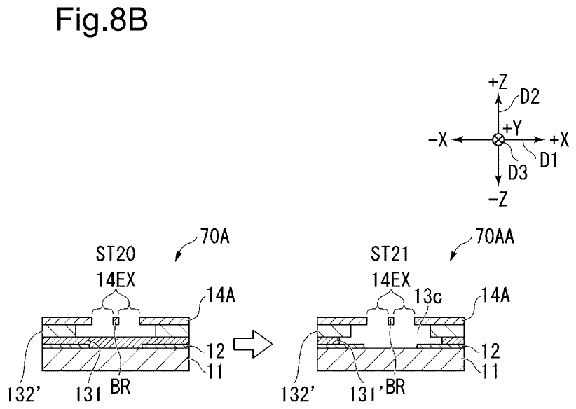

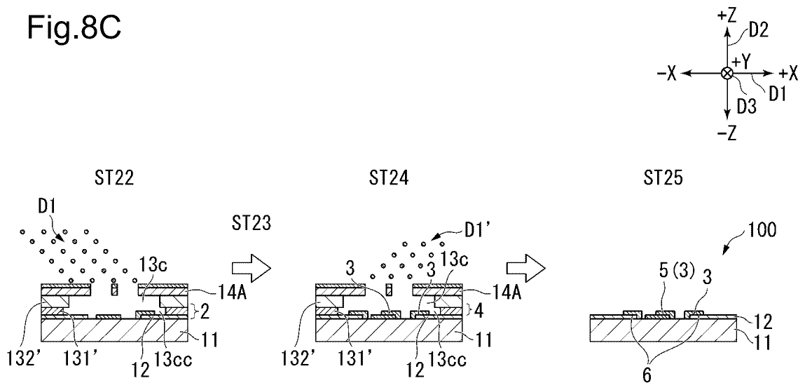

As illustrated in FIG. 8A, a quantum device assembly 70 defined as Sample: B is used. A first sacrificial layer 13′ may include an upper layer unit 132 and a lower layer unit 131. At this time, resist sensitivity of the lower layer unit 131 is larger than resist sensitivity of the upper layer unit 132. For example, the quantum device assembly 70 includes the substrate 11, the superconductor layer 12, the first sacrificial layer 13′, and the second sacrificial layer 14. The upper layer unit 132 is a monomer, and the lower layer unit 131 is silicon oxide or silicon nitride.

As illustrated in FIGS. 8B and 8C, when the quantum device 100 is manufactured, processing is performed according to the flow of steps ST20 to ST25 similar to the above disclosure. Since the first sacrificial layer 13′ includes the upper layer unit 132 and the lower layer unit 131, the cavity 13c is formed in the upper layer unit 132 when EB exposure is performed (step ST20). Next, when a part of the lower layer unit 131 is removed by vapor-phase hydrogen fluoride (step ST21), the lower layer unit 131 may have a cavity 13cc having a dimension larger than the dimension of the cavity 13c in the X direction. At this time, the first deposition layer 2 (second deposition layer 4) is less likely to adhere to the lower layer unit 131. Therefore, the first deposition layer 2 (second deposition layer 4) is easily removed by the vapor-phase hydrogen fluoride. When lift-off is performed with the peeling solution, AL deposited on the first sacrificial layer 13′ is easily peeled off.

### Second Example Embodiment

Hereinafter, an example embodiment according to the present disclosure will be described with reference to the drawings.

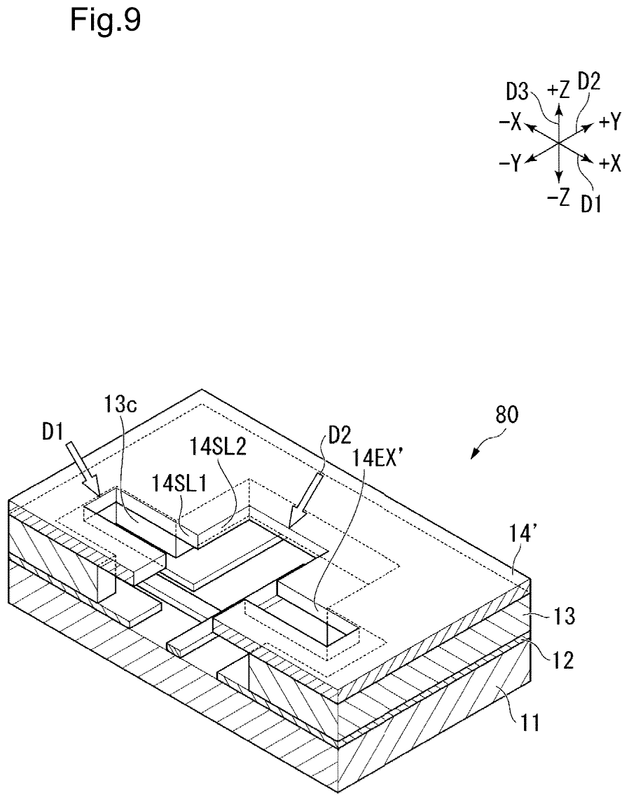

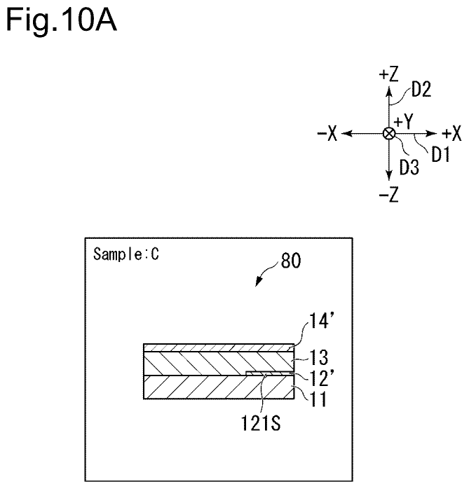

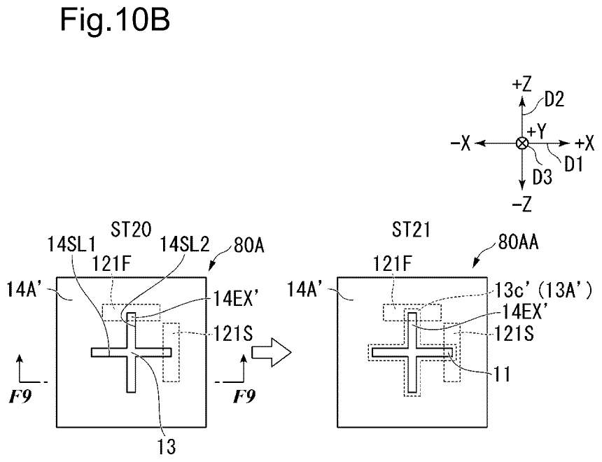

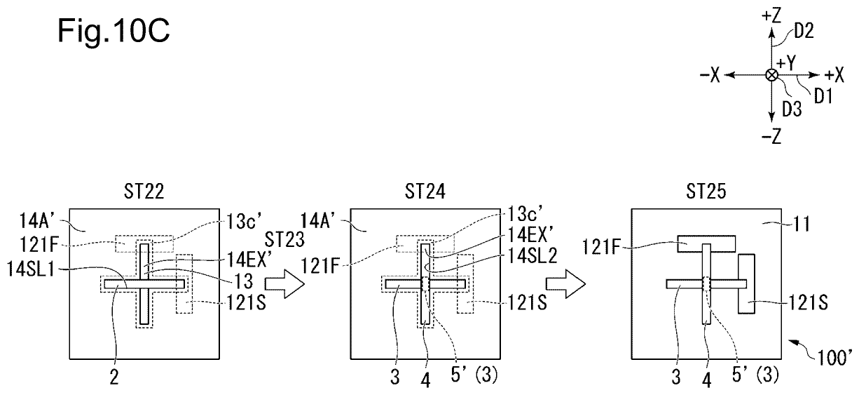

Hereinafter, an example of a configuration of a quantum device assembly 10 in the present disclosure will be described with reference to FIGS. 9, 10A, 10B and 10C.

Components common to those in the above disclosure are denoted by the same reference signs, and detailed description of the components will be omitted.

In deposition of a JJ 5 by the Manhattan method indicated in the second example embodiment, at least one opening 14EX′ is needed.

As described above, when viewed from a lamination direction D3, a second sacrificial layer 14 has the at least one opening 14EX′. The opening 14EX′ includes a first slit 14SL1 extending along a deposition direction D1 and a second slit 14SL2 extending along a deposition direction D2. The first slit 14SL1 and the second slit 14SL2 are coupled. When viewed from the lamination direction D3, the opening 14EX′ has a + shape, an L shape, and a T shape.

As illustrated in FIGS. 9, 10A, 10B and 10C, a quantum device assembly 80 defined as Sample: C includes a substrate 11, a superconductor layer 12′, a first sacrificial layer 13, and the second sacrificial layer 14.

As illustrated in FIG. 10, for example, the second sacrificial layer 14 may be a second sacrificial layer 14A′ having the at least one opening 14EX′. For example, the second sacrificial layer 14 in the following disclosure may be the second sacrificial layer 14A′ having the one opening 14EX′. A quantum device assembly 80A includes the second sacrificial layer 14A′ instead of the second sacrificial layer 14 included in the quantum device assembly 80.

For example, the first sacrificial layer 13 may be a first sacrificial layer 13A′ having a cavity 13c′. The cavity 13c′ is an opening that enlarges the shape of the opening 14EX′ when viewed from the lamination direction D3. The quantum device assembly 80A includes the first sacrificial layer 13A′ instead of the first sacrificial layer 13 included in the quantum device assembly 80.

The superconductor layer 12′ has a positional relationship between two electrodes (a first electrode unit 121F and a second electrode unit 121S) different from that between the electrodes included in a superconductor layer 12. In the superconductor layer 12′, the first electrode unit 121F extends along the first direction D1, and the second electrode unit 121S extends along the second direction D2. When viewed from the lamination direction D3, the second electrode unit 121S is positioned at a position where the first slit 14SL1 extends, and the first electrode unit 121F is positioned at a position where the second slit 14SL2 extends.

When a quantum device 100′ is manufactured, processing is performed according to a flow of steps ST20 to ST25 similar to the above disclosure. A JJ 5′ of the quantum device 100′ may have a different shape compared to the JJ 5 of a quantum device 100.

For example, in step ST22, a manufacturer laminates a pattern of a first deposition layer 2 on the superconductor layer 12 and the substrate 11 from a direction inclined in the first direction (deposition direction D1) relative to the lamination direction D3.

For example, in step ST24, the manufacturer laminates, via an oxide film 3, a part of a second deposition layer 4 on the first deposition layer 2 from a direction inclined in the second direction (deposition direction D2) relative to the lamination direction D3. The manufacturer may rotate a quantum device assembly 80AA after step ST23 or step ST24 by 90 degrees in a substrate surface 11s. At this time, the manufacturer laminates a pattern of the second deposition layer 4 from the direction inclined in the first direction (deposition direction D1) relative to the lamination direction D3.

### (Operation and Effect)

According to the quantum device assembly of the present disclosure, the quantum device assembly 80 includes mask layers including the first sacrificial layer 13 and the second sacrificial layer 14 on the superconductor layer 12.

Focusing on the mask layers, a content rate of an organic material in the first sacrificial layer 13 is smaller than a content rate of the organic material in the second sacrificial layer 14.

Therefore, when the quantum device 100 is manufactured from the quantum device assembly 10, since the first sacrificial layer 13 is removed after the second sacrificial layer 14 is removed, the organic material is less likely to adhere to the superconductor layer 12.

Therefore, the quantum device assembly according to the present disclosure can reduce adhesion of an organic substance to a qubit circuit.

According to a quantum device manufacturing method of the present disclosure, the quantum device assembly includes the mask layers including the first sacrificial layer and the second sacrificial layer on the superconductor layer.

Focusing on the mask layers, the content rate of the organic material in the first sacrificial layer is smaller than the content rate of the organic material in the second sacrificial layer.

Therefore, when the quantum device is manufactured from the quantum device assembly, since the first sacrificial layer is removed after the second sacrificial layer is removed, the organic material is less likely to adhere to the superconductor layer.

Therefore, the quantum device manufacturing method according to the present disclosure can reduce adhesion of the organic substance to the qubit circuit.

According to a quantum device assembly manufacturing method of the present disclosure, the quantum device assembly includes the mask layers including the first sacrificial layer and the second sacrificial layer on the superconductor layer.

Focusing on the mask layers, the content rate of the organic material in the first sacrificial layer is smaller than the content rate of the organic material in the second sacrificial layer.

Therefore, when the quantum device is manufactured from the quantum device assembly, since the first sacrificial layer is removed after the second sacrificial layer is removed, the organic material is less likely to adhere to the superconductor layer.

Therefore, the quantum device assembly manufacturing method according to the present disclosure can reduce adhesion of the organic substance to the qubit circuit.

### Third Example Embodiment

Hereinafter, an example embodiment according to the present disclosure will be described with reference to the drawings.

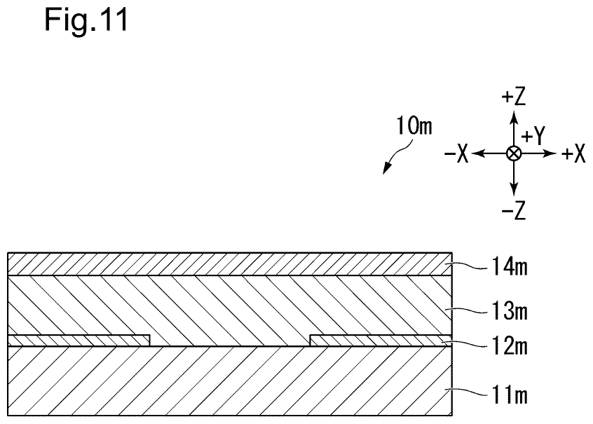

Hereinafter, an example of a configuration of a quantum device assembly in the present disclosure will be described with reference to FIG. 11.

### (Configuration)

A quantum device assembly 10m includes a substrate 11m, a superconductor layer 12m laminated on the substrate 11m, a first sacrificial layer 13m laminated on the superconductor layer 12m, and a second sacrificial layer 14m laminated on the first sacrificial layer 13m, and a content rate of an organic material in the first sacrificial layer 13m is smaller than a content rate of the organic material in the second sacrificial layer 14m.

### (Operation and Effect)

According to the quantum device assembly of the present disclosure, the quantum device assembly 10m includes mask layers including the first sacrificial layer 13m and the second sacrificial layer 14m on the superconductor layer 12m.

Focusing on the mask layers, the content rate of the organic material in the first sacrificial layer 13m is smaller than the content rate of the organic material in the second sacrificial layer 14m.

Therefore, when a quantum device is manufactured from the quantum device assembly 10m, since the first sacrificial layer 13m is removed after the second sacrificial layer 14m is removed, the organic material is less likely to adhere to the superconductor layer 12m.

Therefore, the quantum device assembly according to the present disclosure can reduce adhesion of an organic substance to a qubit circuit.

### Fourth Example Embodiment

Hereinafter, an example embodiment according to the present disclosure will be described with reference to the drawings.

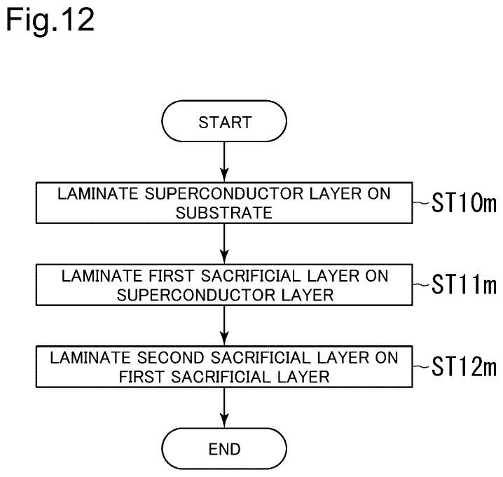

Hereinafter, an example of a quantum device assembly manufacturing method in the present disclosure will be described with reference to FIG. 12.

The quantum device assembly manufacturing method in the present disclosure is implemented according to a flow illustrated in FIG. 12.

The quantum device assembly manufacturing method includes a step of laminating a superconductor layer on a substrate (step ST10m), a step of laminating a first sacrificial layer on the superconductor layer (step ST11m), and a step of laminating a second sacrificial layer on the first sacrificial layer (step ST12m), in which a content rate of an organic material in the first sacrificial layer is smaller than a content rate of the organic material in the second sacrificial layer.

### (Operation and Effect)

According to the quantum device assembly manufacturing method of the present disclosure, a quantum device assembly includes mask layers including the first sacrificial layer and the second sacrificial layer on the superconductor layer.

Focusing on the mask layers, the content rate of the organic material in the first sacrificial layer is smaller than the content rate of the organic material in the second sacrificial layer.

Therefore, when a quantum device is manufactured from the quantum device assembly, since the first sacrificial layer is removed after the second sacrificial layer is removed, the organic material is less likely to adhere to the superconductor layer.

Therefore, the quantum device assembly manufacturing method according to the present disclosure can reduce adhesion of an organic substance to a qubit circuit.

### Fifth Example Embodiment

Hereinafter, an example embodiment according to the present disclosure will be described with reference to the drawings.

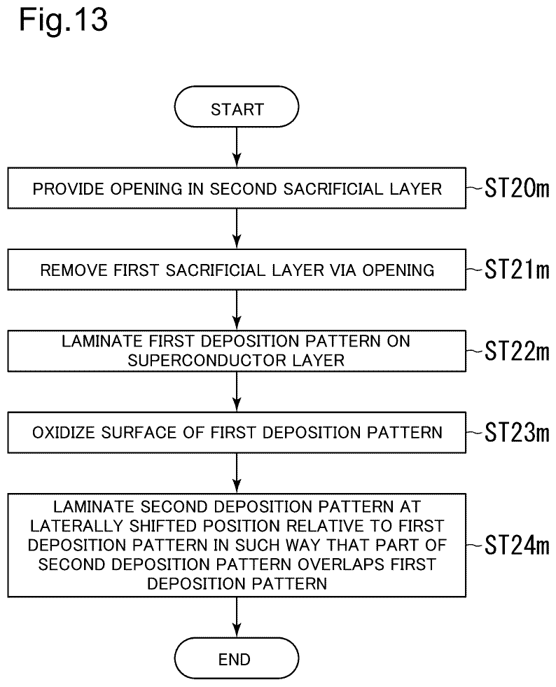

Hereinafter, a quantum device manufacturing method in the present disclosure will be described with reference to FIG. 13.

The quantum device manufacturing method in the present disclosure is implemented according to a flow illustrated in FIG. 13.

The quantum device manufacturing method uses a quantum device assembly including a substrate, a superconductor layer laminated on the substrate, a first sacrificial layer laminated on the superconductor layer, and a second sacrificial layer laminated on the first sacrificial layer, in which a content rate of an organic material in the first sacrificial layer is smaller than a content rate of the organic material in the second sacrificial layer, and includes: a step of providing an opening in the second sacrificial layer by a beam (step ST20m); a step of removing the first sacrificial layer via the opening (step ST21m); a step of laminating a first deposition pattern on the superconductor layer and the substrate (step ST22m); a step of oxidizing a surface of the first deposition pattern (step ST23m); and a step of laminating a second deposition pattern at a laterally shifted position relative to the first deposition pattern in such way that a part of the second deposition pattern overlaps the first deposition pattern (step ST24m).

### (Operation and Effect)

According to the quantum device manufacturing method of the present disclosure, the quantum device assembly includes mask layers including the first sacrificial layer and the second sacrificial layer on the superconductor layer.

Focusing on the mask layers, the content rate of the organic material in the first sacrificial layer is smaller than the content rate of the organic material in the second sacrificial layer.

Therefore, when a quantum device is manufactured from the quantum device assembly, since the first sacrificial layer is removed after the second sacrificial layer is removed, the organic material is less likely to adhere to the superconductor layer.

Therefore, the quantum device assembly manufacturing method according to the present disclosure can reduce adhesion of an organic substance to a qubit circuit.

In a qubit circuit including the Josephson junction device manufactured by the method according to WO 2023/243080 A1, a residue of the resist as an organic substance may adhere to the qubit circuit. In a case where the organic substance adheres to the qubit circuit, a probability that undesirable de-coherence of a qubit occurs may increase depending on an amount of the adhered organic substance.

One of an object of the present disclosure is to provide a quantum device assembly, a quantum device manufacturing method, and a quantum device assembly manufacturing method that solve the problem described above.

According to a quantum device assembly, a quantum device manufacturing method, and a quantum device assembly manufacturing method according to the present disclosure, adhesion of an organic substance to a qubit circuit can be reduced.

While the present disclosure has been particularly shown and described with reference to example embodiments thereof, the present disclosure is not limited to these example embodiments. It will be understood by those of ordinary skill in the art that various changes in form and details including shapes and materials may be made therein without departing from the spirit and scope of the present disclosure as defined by the claims. And each embodiment can be appropriately combined with other embodiments.

### <Another Modification>

In the above example, the electron beam is used when the opening is provided in the second sacrificial layer, but an ion beam or a light beam may be used.

Some or all of the above example embodiments may also be described as the following Supplementary Notes, but are not limited to the following.

### (Supplementary Note 1)

A quantum device assembly including:
a substrate;
a superconductor layer laminated on the substrate;
a first sacrificial layer laminated on the superconductor layer; and
a second sacrificial layer laminated on the first sacrificial layer,
a content rate of an organic material in the first sacrificial layer being smaller than a content rate of the organic material in the second sacrificial layer.

### (Supplementary Note 2)

The quantum device assembly according to Supplementary Note 1, in which
the superconductor layer includes a first electrode unit and a second electrode unit separated from the first electrode unit in a first direction, and
the second sacrificial layer has an opening between the first electrode unit and the second electrode unit when viewed from a lamination direction.

### (Supplementary Note 3)

The quantum device assembly according to Supplementary Note 2, in which
the opening includes a first slit along the first direction and a second slit along a second direction intersecting the first direction, and
the first slit and the second slit are coupled.

### (Supplementary Note 4)

The quantum device assembly according to Supplementary Note 2 or 3, in which
the first sacrificial layer has a cavity communicating with the opening.

### (Supplementary Note 5)

The quantum device assembly according to any one of Supplementary Notes 1 to 4, in which the first sacrificial layer includes silicon oxide or silicon nitride.

### (Supplementary Note 6)

The quantum device assembly according to any one of Supplementary Notes 1 to 5, in which the second sacrificial layer includes a polymer.

### (Supplementary Note 7)

The quantum device assembly according to Supplementary Note 6, in which
the second sacrificial layer includes an upper layer unit and a lower layer unit, and
resist sensitivity of the lower layer unit is larger than resist sensitivity of the upper layer unit.

### (Supplementary Note 8)

The quantum device assembly according to any one of Supplementary Notes 1 to 7, in which
the superconductor layer includes titanium nitride, titanium niobium nitride, tantalum, or molybdenum-rhenium alloy.

### (Supplementary Note 9)

A quantum device manufacturing method using a quantum device assembly including a substrate, a superconductor layer laminated on the substrate, a first sacrificial layer laminated on the superconductor layer, and a second sacrificial layer laminated on the first sacrificial layer, in which a content rate of an organic material in the first sacrificial layer is smaller than a content rate of the organic material in the second sacrificial layer, the quantum device manufacturing method including:
providing an opening in the second sacrificial layer by a beam;
removing the first sacrificial layer via the opening;
laminating a first deposition pattern on the superconductor layer and the substrate;
oxidizing a surface of the first deposition pattern; and
laminating a second deposition pattern at a laterally shifted position relative to the first deposition pattern in such way that a part of the second deposition pattern overlaps the first deposition pattern.

### (Supplementary Note 10)

The quantum device manufacturing method according to Supplementary Note 9, in which
the superconductor layer includes a first electrode unit and a second electrode unit separated from the first electrode unit in a first direction,
in the providing the opening, the opening is provided between the first electrode unit and the second electrode unit, and
in the laminating the first deposition pattern, the first deposition pattern is laminated on the superconductor layer and the substrate from a direction inclined relative to a lamination direction of the quantum device assembly.

### (Supplementary Note 11)

The quantum device manufacturing method according to Supplementary Note 10, in which
the opening includes a first slit along the first direction and a second slit along a second direction intersecting the first direction,
the first slit and the second slit are coupled,
in the laminating the first deposition pattern, the first deposition pattern is laminated on the superconductor layer and the substrate from a direction inclined in the first direction relative to the lamination direction of the quantum device assembly, and
in the laminating the second deposition pattern, the part of the second deposition pattern is laminated on the first deposition pattern from a direction inclined in the second direction relative to the lamination direction of the quantum device assembly.

### (Supplementary Note 12)

The quantum device manufacturing method according to any one of Supplementary Notes 9 to 11, in which
in the removing the first sacrificial layer, the first sacrificial layer is removed by vapor-phase hydrogen fluoride.

### (Supplementary Note 13)

The quantum device manufacturing method according to Supplementary Note 12, in which
the superconductor layer includes titanium nitride, titanium niobium nitride, tantalum, or molybdenum-rhenium alloy.

### (Supplementary Note 14)

A quantum device assembly manufacturing method including:
laminating a superconductor layer on a substrate;
laminating a first sacrificial layer on the superconductor layer; and
laminating a second sacrificial layer on the first sacrificial layer,
a content rate of an organic material in the first sacrificial layer being smaller than a content rate of the organic material in the second sacrificial layer.

1. A quantum device assembly comprising:
a substrate;
a superconductor layer laminated on the substrate;
a first sacrificial layer laminated on the superconductor layer; and
a second sacrificial layer laminated on the first sacrificial layer,
a content rate of an organic material in the first sacrificial layer being smaller than a content rate of the organic material in the second sacrificial layer.

2. The quantum device assembly according to claim 1, wherein
the superconductor layer includes a first electrode unit and a second electrode unit separated from the first electrode unit in a first direction, and
the second sacrificial layer has an opening between the first electrode unit and the second electrode unit when viewed from a lamination direction.

3. The quantum device assembly according to claim 2, wherein
the opening includes a first slit along the first direction and a second slit along a second direction intersecting the first direction, and
the first slit and the second slit are coupled.

4. The quantum device assembly according to claim 2, wherein
the first sacrificial layer has a cavity communicating with the opening.

5. The quantum device assembly according to claim 1, wherein
the first sacrificial layer includes silicon oxide or silicon nitride.

6. The quantum device assembly according to claim 1, wherein
the second sacrificial layer includes a polymer.

7. The quantum device assembly according to claim 6, wherein
the second sacrificial layer includes an upper layer unit and a lower layer unit, and
resist sensitivity of the lower layer unit is larger than resist sensitivity of the upper layer unit.

8. The quantum device assembly according to claim 1, wherein
the superconductor layer includes titanium nitride, titanium niobium nitride, tantalum, or molybdenum-rhenium alloy.

9. A quantum device manufacturing method using a quantum device assembly including a substrate, a superconductor layer laminated on the substrate, a first sacrificial layer laminated on the superconductor layer, and a second sacrificial layer laminated on the first sacrificial layer, in which a content rate of an organic material in the first sacrificial layer is smaller than a content rate of the organic material in the second sacrificial layer, the quantum device manufacturing method comprising:
providing an opening in the second sacrificial layer by a beam;
removing the first sacrificial layer via the opening;
laminating a first deposition pattern on the superconductor layer and the substrate;
oxidizing a surface of the first deposition pattern; and
laminating a second deposition pattern at a laterally shifted position relative to the first deposition pattern in such way that a part of the second deposition pattern overlaps the first deposition pattern.

10. The quantum device manufacturing method according to claim 9, wherein
the superconductor layer includes a first electrode unit and a second electrode unit separated from the first electrode unit in a first direction,
in the providing the opening, the opening is provided between the first electrode unit and the second electrode unit, and
in the laminating the first deposition pattern, the first deposition pattern is laminated on the superconductor layer and the substrate from a direction inclined relative to a lamination direction of the quantum device assembly.

11. The quantum device manufacturing method according to claim 10, wherein
the opening includes a first slit along the first direction and a second slit along a second direction intersecting the first direction,
the first slit and the second slit are coupled,
in the laminating the first deposition pattern, the first deposition pattern is laminated on the superconductor layer and the substrate from a direction inclined in the first direction relative to the lamination direction of the quantum device assembly, and
in the laminating the second deposition pattern, the part of the second deposition pattern is laminated on the first deposition pattern from a direction inclined in the second direction relative to the lamination direction of the quantum device assembly.

12. The quantum device manufacturing method according to claim 9, wherein
in the removing the first sacrificial layer, the first sacrificial layer is removed by vapor-phase hydrogen fluoride.

13. The quantum device manufacturing method according to claim 12, wherein
the superconductor layer includes titanium nitride, titanium niobium nitride, tantalum, or molybdenum-rhenium alloy.

14. A quantum device assembly manufacturing method comprising:
laminating a superconductor layer on a substrate;
laminating a first sacrificial layer on the superconductor layer; and
laminating a second sacrificial layer on the first sacrificial layer,
a content rate of an organic material in the first sacrificial layer being smaller than a content rate of the organic material in the second sacrificial layer.
